(19) United States
(12) Patent Application Publication
(10) Pub. No.: US 2005/0007144 A1
(43) Pub. Date: Jan. 13, 2005

(54) Fuel cell testing system having an energy conversion system for providing a useful output

(76) Inventors: Norman A. Freeman, Toronto (CA); Ravi B. Gopal, Oakville (CA)

Correspondence Address: BERESKIN AND PARR, SCOTIA PLAZA, 40 KING STREET WEST-SUITE 4000 BOX 401, TORONTO, ON, M5H 3Y2, CA

(21) Appl. No.: 10/845,107

(22) Filed: May 14, 2004

Related U.S. Application Data
(60) Provisional application No. 60/470,427, filed on May 15, 2003.

(51) Int. Cl. G01R 31/00

(52) U.S. Cl. 324/771; 700/286

(57) ABSTRACT

The electrical energy produced by a fuel cell under test is typically dumped in the form of heat energy radiated from a controllable variable load included in a conventional fuel cell testing system. This practice is wasteful since the electrical energy produced is not immediately employed to do useful work, stored for later use or sold to a power company after appropriate conversion. According to aspects of some embodiments of the present invention there is provided a fuel cell testing system having an energy conversion system that converts electrical energy produced by a fuel cell under test into another reliable form of energy that can be employed for some useful end, as opposed to simply dumping it as radiated heat energy.

This application claims the benefit of U.S. Provisional Application No. 60/470,427, which was filed on May 15, 2003, and the entire contents of which are hereby incorporated by reference.

### FIELD OF THE INVENTION

This invention relates generally to fuel cell testing systems, and, in particular to an energy conversion system provided with a fuel cell testing station for providing a useful output.

### BACKGROUND OF THE INVENTION

In order to test the performance of a fuel cell (or a fuel cell stack), a stand-alone fuel cell testing station is usually employed. A fuel cell testing station simulates operating conditions for a fuel cell being tested and monitors various parameters indicating the performance of the fuel cell or the fuel cell stack.

In order to simulate various operating conditions, a fuel cell testing station is usually capable of supplying various combinations of process reactants (e.g. hydrogen, air, steam, etc.) to a fuel cell, as well as controlling parameters related to a particular process reactant such as temperature, pressure, flow rate and relative humidity. A fuel cell testing station also typically includes a controllable variable load that is connectable between anode and cathode terminals of a fuel cell being tested. The controllable variable load can be used to change the electrical energy outputs, such as DC voltage and current, drawn from the fuel cell under test. The electrical energy drawn from the fuel cell under test using a conventional fuel cell testing station is simply dissipated as heat radiated from the variable load.

### SUMMARY OF THE INVENTION

According to an aspect of an embodiment of the invention there is provided a system for testing a fuel cell and generating electrical power, which includes: a fuel cell test station for testing a fuel cell, the fuel cell test station being operable to control and monitor the fuel cell; and, an energy conversion system for converting raw electrical DC power directly coupled from the fuel cell into a usable form of electrical power.

In some embodiments the energy conversion system further includes: an input isolator connectable to the fuel cell for protecting the energy conversion system from surges in power originating in the fuel cell; an output isolator connectable to a load, for protecting both the load and the energy conversion system from power surges originating from one another, respectively; and, a DC-DC converter, connected to receive raw electrical DC power through the input isolator, for converting the raw electrical DC power into the usable form of electrical power, and for supplying the usable form of electrical power to the load through the output isolator.

In such embodiments, the usable form of electrical power includes, but is not limited to, one of a substantially constant DC voltage and a substantially constant DC current.

In even other embodiments the input isolator includes: a threshold detector for determining whether or not the raw electrical DC power it is between a lower and an upper threshold and for producing a positive signal if it is and producing a negative signal if it is not; and a switch coupled to receive the raw electrical DC power and the signals from the threshold detector, the switch being operable to couple the raw electrical DC power to the DC-DC converter upon receiving the positive signal from the threshold detector and being operable to not couple the raw electrical DC power to the DC-DC converter upon receiving the negative signal.

In related embodiments the energy conversion system further includes: a DC-AC converter connected in series between the DC-DC converter and the output isolator, for changing DC power to a usable form of AC power. In such embodiments, the usable form of electrical power includes, but is not limited to, one of a single phase AC voltage, a single phase AC current, a multi-phase AC voltage and a multi-phase AC current.

In some embodiments the input isolator includes: a threshold detector for determining whether or not the raw electrical DC power is above a lower threshold and for producing a positive signal if it is and producing a negative signal if it is not; and a switch coupled to receive the raw electrical DC power and the signals from the threshold detector, the switch being operable to couple the raw electrical DC power to the DC-DC converter upon receiving the positive signal from the threshold detector and being operable to not couple the raw electrical DC power to the DC-DC converter upon receiving the negative signal.

In other embodiments the input isolator includes: a threshold detector for determining whether or not the raw electrical DC power is below an upper threshold and for producing a positive signal if it is and producing a negative signal if it is not; and a switch coupled to receive the raw electrical DC power and the signals from the threshold detector, the switch being operable to couple the raw electrical DC power to the DC-DC converter upon receiving the positive signal from the threshold detector and being operable to not couple the raw electrical DC power to the DC-DC converter upon receiving the negative signal.

In some embodiments the output isolator is one of an isolation transformer, a BJT and a MESFET.

In some embodiments, the energy conversion system is adapted to convert the raw electrical DC power coupled directly from the fuel cell to a AC power compatible with an electric power grid. Moreover, in related embodiments the energy conversion system also includes a synchronizing device for synchronizing the converted AC power with the electric power grid.

Other aspects and features of the present invention will become apparent, to those ordinarily skilled in the art, upon review of the following description of the specific embodiments of the invention.

### BRIEF DESCRIPTION OF THE DRAWINGS

For a better understanding of the present invention, and to show more clearly how it may be carried into effect, reference will now be made, by way of example, to the accompanying drawings, which illustrate aspects of embodiments of the present invention and in which:

FIG. 1 is a simplified schematic diagram a fuel cell testing station having an energy conversion system according to aspects of an embodiment of the invention in combination with a fuel cell;

FIG. 2 is a simplified schematic diagram of a very specific example of an energy conversion system according to aspects of an embodiment of the invention; and

FIG. 3 is a simplified schematic diagram of another very specific example of an energy conversion system according to aspects of an embodiment of the invention.

### DETAILED DESCRIPTION OF THE INVENTION

The electrical energy produced by a fuel cell under test is typically dumped in the form of heat energy radiated from a controllable variable load included in a conventional fuel cell testing system. This practice is wasteful since the electrical energy produced is not immediately employed to do useful work, stored for later use or sold to a power company after appropriate conversion. One reason that the electrical energy is not employed for useful purposes is that the DC voltages or currents directly coupled from a fuel cell under test are not typically reliable enough to be immediately used for some useful end.

According to aspects of some embodiments of the present invention there is provided a fuel cell testing system having an energy conversion system that converts electrical energy produced by a fuel cell under test into another reliable form of energy that can be employed for some useful end, as opposed to simply dumping it as radiated heat energy. That is, some embodiments of the invention include an energy conversion means for converting electrical energy produced by a fuel cell under test into some useful form of energy.

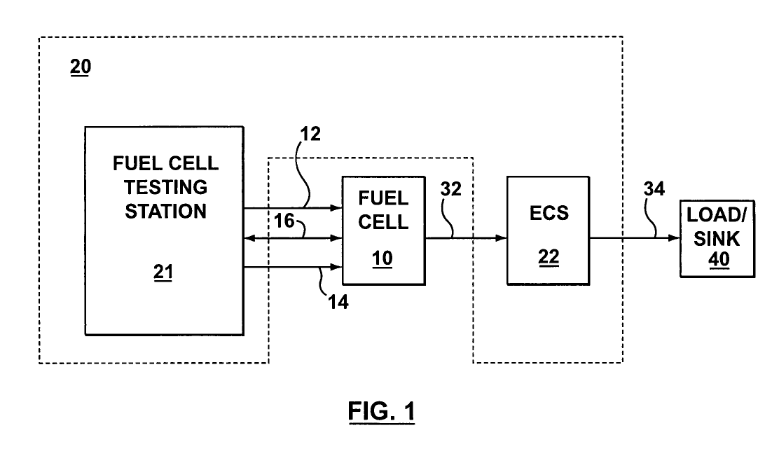

Referring to FIG. 1, according to aspects of an embodiment of the invention, shown is a simplified schematic diagram of a fuel cell testing system 20 having an Energy Conversion System (ECS) 22. More specifically, the schematic diagram shown in FIG. 1 includes the fuel cell testing system 20 having the ECS 22 and a fuel cell testing station 21. The fuel cell testing station 21 and the ECS 22 are both coupled to a fuel cell 10, and the ECS 22 is further coupled to a load (or sink) 40.

A typical fuel cell testing station includes a suitable number and combination of connections to a fuel cell being tested for supplying and evacuating process gases and/or fluids, controlling operating conditions and for monitoring various parameters that indicate the performance of the fuel cell during testing. For the sake of simplicity not all of these connections have been illustrated in FIG. 1. Connections between the fuel cell testing station 21 and the fuel cell 10 shown, by way of specific example only, in FIG. 1 include a fuel (e.g. hydrogen) supply line 12, an oxidant supply line 14 and control/feedback bus 16. The fuel cell 10 is coupled to the ECS 22 via a DC power-output line 32.

In other embodiments a fuel cell testing station circulates at least one of coolant, fuel and oxidant to and from a fuel cell under test via respective supply and return lines. In such embodiments, at least one return line for each process gas and/or fluid that is circulated is provided. Alternatively, in other embodiments, similar to the configuration illustrated in FIG. 1, a fuel cell may be designed to operate in a dead-end mode, where one or more process gases and/or fluids is supplied to the fuel cell and not circulated back to the fuel cell station or other supply source. Moreover, it would be appreciated by those skilled in the art that a fuel cell testing system includes a suitable combination of hardware, software, firmware and mechanical systems required to support one or modes of operation.

As shown in FIG. 1, the ECS 22 is coupled to deliver power to the load 40 via delivery line 34. In some embodiments an ECS includes various other connections for monitoring and controlling inputs from a fuel cell, outputs to a load/sink and to the rest of a fuel cell testing system to provide feedback and status information to the fuel cell testing system.

Typically a fuel cell is operated such that the fuel cell provides electrical energy in a DC form. That is, a fuel cell is operated so as to provide at least one of a constant voltage level and/or current that may be employed for some end. With further reference to the fuel cell 10, illustrated schematically in FIG. 1, the fuel cell 10 generates raw electrical power in DC form that is coupled to the ECS 22 via the DC power-output line 32. As noted earlier the raw electrical DC power provided by a fuel cell (e.g. fuel cell 10) under test is not reliable enough to be safely employed by a load/sink.

The ECS 22 operates to covert the raw electrical DC power, generated during testing, into a desirable and usable form. In some embodiments, an ECS provided with a fuel cell testing system employs a lower threshold to which the raw electrical DC power is compared. In other embodiments the output voltage or current of the fuel cell can be used in similar such comparisons. If the raw electrical DC power is below the lower threshold, the ECS does not operate to convert the raw electrical DC power into another desirable and usable form, since the raw electrical DC power may not be sufficiently high to warrant conversion as the output energy from the conversion process is less than the energy required to carry out the conversion process. In some embodiments, the specific number for the lower threshold is dependent on the expected magnitude of the electrical power obtained from the fuel cell under test. Additionally, in related embodiments the lower threshold is further dependent on the use of the output from an ECS. In other embodiments, an ECS employs both an upper and a lower threshold to which the raw electrical DC power is compared. If the raw electrical DC power is not between the upper and lower thresholds, the ECS does not operate to convert the raw electrical DC power into another desirable and usable form. In such embodiments, the DC power may be too small to warrant conversion or may be so large that it would damage portions of the ECS. Both of the upper and lower thresholds can be based on a number of factors that include, but are not limited to: current and/or voltage handling capability of the ECS; expected use for the electrical output of the ECS; and, the expected electrical output directly coupled from the fuel cell under test.

In some embodiments, in instances where the raw electrical DC power (or voltage or current coupled directly from the fuel cell under test) does not satisfy one or more thresholds (e.g. The lower and/or upper threshold mentioned above), the raw electrical DC power (or voltage or current coupled directly from the fuel cell under test) is coupled to a shunt resistor and is dissipated as heat.

In some embodiments, forms of desirable electrical outputs from an ECS provided with a fuel cell testing system include DC current and/or voltage, single-phase AC current and/or voltage, and multi-phase AC current and/or voltage. These different forms of desirable electrical outputs can be employed to do various forms of useful work. For example, if an ECS provided with a fuel cell testing system converts raw electrical DC power, obtained directly from a fuel cell under test, to single-phase AC power, the single-phase AC power may be employed to drive an AC motor. In another example, if an ECS provided with a fuel cell testing system converts raw electrical DC power, obtained directly from a fuel cell under test, to multi-phase AC power that is compatible with an electrical power grid, the multi-phase AC power may be used locally or sold to a utility company. Accordingly, in some embodiments, a fuel cell testing station and ECS is used to generate power for the lab or plant where the fuel cell testing station is located, and hence reducing the power consumed by the lab or plant from a power grid and in some instances lowering the cost of operating such a lab or plant.

A system for enabling the real time buying and selling of electricity generated by fuel cell powered vehicles has been disclosed in US 2002/0132144 and is hereby incorporated by reference in its entirety. Those skilled in the art would appreciate that aspects of such a system can be combined with embodiments of the present invention and further utilized for selling electrical power generated by a fuel cell under test in combination with a fuel cell testing system that is provided with an ECS according to aspects of an embodiment of the invention.

In alternative embodiments, the electrical power recovered by a fuel cell testing system provided with an ECS can be stored using any number of power storage devices, such as a bank of batteries. In other embodiments the electrical power is immediately employed to power an electrolysis device, additionally included in a fuel cell testing system. In such embodiments, the electrolysis device is used to locally produce fuel and oxidant (e.g. hydrogen and oxygen) for the fuel cell under test, which may further reduce operating costs during the testing of the fuel cell.

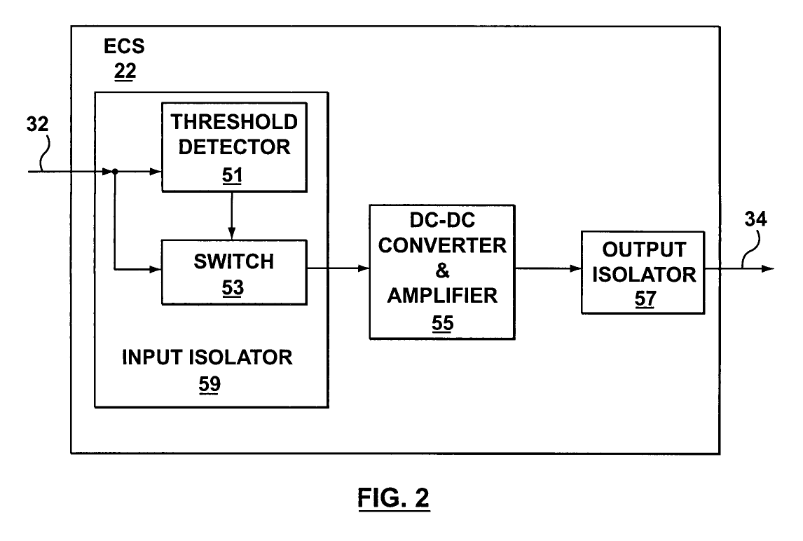

Referring to FIG. 2 shown is a very specific example of a simplified schematic diagram of the ECS 22 shown generally in FIG. 1. The ECS 22 includes an input isolator 59, a DC-DC converter and amplifier 55, and an output isolator 57, connected in series, respectively.

The input isolator 59 is connectable externally to receive raw electrical DC power obtained from the fuel cell 10 via DC power-output line 32. The input isolator 59 is also coupled to the DC-DC converter and amplifier 55, which is in turn coupled in series to the output isolator 57. The output isolator 57 is connectable externally to provide a usable form of electric energy to the load 40.

The input isolator 59 includes a threshold detector 51 and a switch 53 that are each coupled to receive the raw electrical DC power via DC power-output line 32. The threshold detector 51 is also connected to the switch 53 to provide the switch 53 with a control signal. The switch 53 is connected to the DC-DC converter and amplifier 55.

The output isolator 57 is a suitable combination of electrical circuitry that both protects the ECS 22 from feedback from a load or power grid and protects a load or power grid from surges in power within the ECS 22. In some embodiments, the output isolator 57 is an isolation transformer. In other embodiments the output isolator 57 is a Bipolar Junction Transistor or a Gallium Arsenide (GaAs) MESFET.

In operation, the ECS 22 shown in FIG. 2 receives the raw electrical DC power via DC power-output line 32 from the fuel cell 10 (shown in FIG. 1). The raw electrical DC power is coupled into the input isolator 59 where it is received by both the threshold detector 51 and the switch 53, in parallel. The threshold detector 51 compares the magnitude of the raw electrical DC power to at least one of a lower and upper threshold to determine whether or not conversion of the raw electrical DC power into a more usable form of electrical energy is safe and/or justified given the limits of the other elements of the ECS 22 and their input power requirements. In other words, the threshold detector 51 determines whether or not the raw electrical DC power will yield enough usable energy to warrant conversion and in some instances whether or not the conversion process can occur without damaging the remainder of the ECS 22.

If the threshold detector 51, determines that the raw electrical DC power should not and/or cannot be converted into a more usable form of energy, the threshold detector 51 sends a negative control signal to the switch 53, which, in turn, does not couple the raw electrical DC power any further into the ECS 22. On the other hand, if the threshold detector 51 determines that the raw electrical DC power meets the requirements for conversion, the threshold detector 51 sends a positive control signal to the switch 53. Upon receiving the positive control signal, the switch 53 couples the raw electrical DC power to the DC-DC converter and amplifier 55.

The DC-DC converter and amplifier 55 converts the raw electrical DC power into a usable form of DC power that has a substantially constant magnitude and/or voltage level and/or current level. The voltage level may be higher or lower than the voltage associated directly with the raw electrical DC power. The DC-DC converter and amplifier 55 then couples the DC power to the output isolator 57 that is externally coupled to deliver the DC power to the load 40.

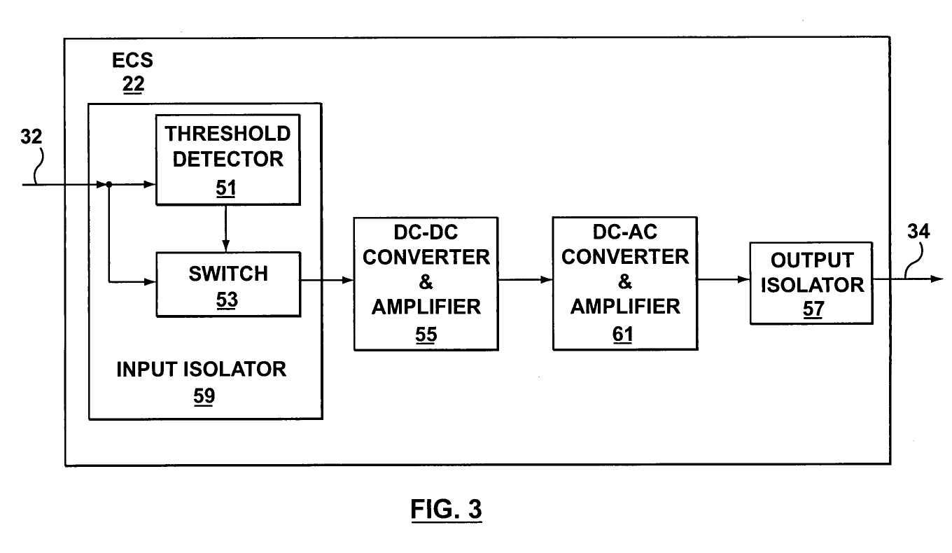

Referring to FIG. 3 shown is another very specific example of a simplified schematic diagram of the ECS 22 shown generally in FIG. 1. The ECS 22, illustrated schematically in FIG. 3, is similar to the ECS 22 shown in FIG. 2 in that the ECS 22 (of FIG. 3) includes the input isolator 59, the DC-DC converter and amplifier 55, and the output isolator 57. However, additionally, the ECS 22 shown in FIG. 3 also includes a DC-AC converter and amplifier 61 connected in series between the DC-DC converter and amplifier 55 and the output isolator 57.

The operation of the components illustrated in FIG. 3 that are common to FIG. 2 is substantially identical to what was described above with reference to FIG. 2. The component not shown in FIG. 2 is the DC-AC converter and amplifier 61; and, in operation, the DC-AC converter and amplifier 61 accepts DC power from the DC-DC converter and amplifier 55 and converts it to at least one of single phase and multi-phase AC power, which is, in turn, coupled to a load 40 through the output isolator 40.

What has been described is merely illustrative of the application of the principles of the invention. Other arrangements can be implemented by those skilled in the art without departing from the scope of the present invention as defined by the following claims.

1. A system for testing a fuel cell and generating electrical power, comprising:
a fuel cell test station for testing a fuel cell, the fuel cell test station being operable to control and monitor the fuel cell; and
an energy conversion system for converting raw electrical DC power directly coupled from the fuel cell into a usable form of electrical power.

2. A system according to claim 1, wherein the energy conversion system further comprises:
an input isolator connectable to the fuel cell for protecting the energy conversion system from surges in power originating in the fuel cell;
an output isolator connectable to a load, for protecting both the load and the energy conversion system from power surges originating from one another, respectively; and
a DC-DC converter, connected to receive raw electrical DC power through the input isolator, for converting the raw electrical DC power into the usable form of electrical power, and for supplying the usable form of electrical power to the load through the output isolator.

3. A system according to claim 2, wherein the usable form of electrical power is in the form of one of a substantially constant DC voltage and a substantially constant DC current.

4. A system according to claim 2, wherein the input isolator comprises:
a threshold detector for determining whether or not the raw electrical DC power is above a lower threshold and for producing a positive signal if it is and producing a negative signal if it is not; and
a switch coupled to receive the raw electrical DC power and the signals from the threshold detector, the switch being operable to couple the raw electrical DC power to the DC-DC converter upon receiving the positive signal from the threshold detector and being operable to not couple the raw electrical DC power to the DC-DC converter upon receiving the negative signal.

5. A system according to claim 2, wherein the input isolator comprises:
a threshold detector for determining whether or not the raw electrical DC power is below an upper threshold and for producing a positive signal if it is and producing a negative signal if it is not; and
a switch coupled to receive the raw electrical DC power and the signals from the threshold detector, the switch being operable to couple the raw electrical DC power to the DC-DC converter upon receiving the positive signal from the threshold detector and being operable to not couple the raw electrical DC power to the DC-DC converter upon receiving the negative signal.

6. A system according to claim 2, wherein the input isolator comprises:
a threshold detector for determining whether or not the raw electrical DC power it is between a lower and an upper threshold and for producing a positive signal if it is and producing a negative signal if it is not; and
a switch coupled to receive the raw electrical DC power and the signals from the threshold detector, the switch being operable to couple the raw electrical DC power to the DC-DC converter upon receiving the positive signal from the threshold detector and being operable to not couple the raw electrical DC power to the DC-DC converter upon receiving the negative signal.

7. A system according to claim 2, wherein the energy conversion system further comprises:
a DC-AC converter connected in series between the DC-DC converter and the output isolator, for changing DC power to a usable form of AC power.

8. A system according to claim 7, wherein the usable form of electrical power is in the form of one of a single phase AC voltage, a single phase AC current, a multi-phase AC voltage and a multi-phase AC current.

9. A system according to claim 2, wherein the output isolator is one of an isolation transformer, a BJT and a MESFET.

10. A system according to claim 1, wherein the energy conversion system is adapted to convert the raw electrical DC power coupled directly from the fuel cell to a form of AC power compatible with an electric power grid.

11. A system according to claim 10, wherein the energy conversion system further comprises a synchronizing device for synchronizing the converted AC power with the electric power grid.

12. A system for testing a fuel cell and generating electrical power, comprising:
a fuel cell test station for testing a fuel cell, the fuel cell test station being operable to control and monitor the fuel cell; and
an energy conversion system for converting raw voltage directly coupled from the fuel cell into a usable form of electrical energy.

13. A system according to claim 12, wherein the energy conversion system further comprises:
an input isolator connectable to the fuel cell for protecting the energy conversion system from surges in voltage level originating in the fuel cell;
an output isolator connectable to a load, for protecting both the load and the energy conversion system from voltage level surges originating from one another, respectively; and
a DC-DC converter, connected to receive raw voltage directly coupled from the fuel cell through the input isolator, for converting the raw voltage into the usable form of electrical energy, and for supplying the usable form of electrical energy to the load through the output isolator.

14. A system according to claim 13, wherein the usable form of electrical energy is in the form of one of a substantially constant DC voltage and a substantially constant DC current.

15. A system according to claim 13, wherein the input isolator comprises:
a threshold detector for determining whether or not the raw voltage is above a lower threshold and for producing a positive signal if it is and producing a negative signal if it is not; and
a switch coupled to receive the raw voltage and the signals from the threshold detector, the switch being operable to couple the raw voltage to the DC-DC converter upon receiving the positive signal from the threshold detector and being operable to not couple the raw voltage to the DC-DC converter upon receiving the negative signal.

16. A system according to claim 13, wherein the input isolator comprises:
a threshold detector for determining whether or not the raw voltage is below an upper threshold and for producing a positive signal if it is and producing a negative signal if it is not; and
a switch coupled to receive the raw voltage and the signals from the threshold detector, the switch being operable to couple the raw voltage to the DC-DC converter upon receiving the positive signal from the threshold detector and being operable to not couple the raw voltage to the DC-DC converter upon receiving the negative signal.

17. A system according to claim 13, wherein the input isolator comprises:
a threshold detector for determining whether or not the raw voltage it is between a lower and an upper threshold and for producing a positive signal if it is and producing a negative signal if it is not; and
a switch coupled to receive the raw voltage and the signals from the threshold detector, the switch being operable to couple the raw voltage to the DC-DC converter upon receiving the positive signal from the threshold detector and being operable to not couple the raw voltage to the DC-DC converter upon receiving the negative signal.

18. A system according to claim 13, wherein the energy conversion system further comprises:
a DC-AC converter connected in series between the DC-DC converter and the output isolator, for producing a usable form of AC energy.

19. A system according to claim 18, wherein the usable form of electrical energy is in the form of one of a single phase AC voltage, a single phase AC current, a multi-phase AC voltage and a multi-phase AC current.

20. A system according to claim 13, wherein the output isolator is one of an isolation transformer, a BJT and a MESFET.

21. A system according to claim 12, wherein the energy conversion system is adapted to convert the raw voltage coupled directly from the fuel cell to a form of AC energy compatible with an electric power grid.

22. A system according to claim 21, wherein the energy conversion system further comprises a synchronizing device for synchronizing the converted AC energy with the electric power grid.
